(19) United States
(12) Patent Application Publication
(10) Pub. No.: US 2019/0212803 A1
(43) Pub. Date: Jul. 11, 2019

(54) DATA CENTER POWER CONSUMPTION CHARACTERIZATION

(71) Applicants: Sandeep Gupta, Phoenix, AZ (US); Ayan Banerjee, Mesa, AZ (US); Sushil Gupta, New Delhi (IN)

(72) Inventors: Sandeep Gupta, Phoenix, AZ (US); Ayan Banerjee, Mesa, AZ (US); Sushil Gupta, New Delhi (IN)

(73) Assignee: Arizona Board of Regents on behalf of Arizona State University, Scottsdale, AZ (US)

(21) Appl. No.: 16/356,380

(22) Filed: Mar. 18, 2019

Related U.S. Application Data
(62) Division of application No. 15/105,284, filed on Jun. 16, 2016.
(60) Provisional application No. 61/917,455, filed on Dec. 18, 2013.

(51) Int. Cl. G06F 1/3228; G06F 1/3203; H02J 13/00; G01R 21/00; H02J 3/26

(52) U.S. Cl. CPC G06F 1/3228; G06F 1/3203; H02J 2003/007; G01R 21/00; H02J 3/26; H02J 13/001

(57) ABSTRACT

A method for characterizing the power consumption of a data center includes the steps of measuring one or more power consumption parameters associated with the data center when no workload is present, generating one or more workloads in the data center in which one or more three phase PDUs include an imbalanced phase, measuring one or more power consumption parameters associated with the data center during the one or more generated workflows, and characterizing the power consumption of the data center due to phase imbalance of the one or more three phase PDUs based on the measurements. By characterizing the power consumption of the data center due to phase imbalance based on empirical measurements, an accurate characterization of the power consumption attributable to phase imbalance can be achieved.

### RELATED APPLICATIONS

This application is a divisional application of U.S. patent application Ser. No. 15/105,284, filed Jun. 16, 2016, which is a 35 U.S.C. § 371 national phase filing of International Application No. PCT/US14/71176, filed Dec. 18, 2014, which claims priority to U.S. Provisional Application No. 61/917,455, filed Dec. 18, 2013, the disclosures of which are incorporated herein by reference in their entireties.

### GOVERNMENT SUPPORT

Please note that this invention was funded by a government agency. This invention was made with government support under 0855277 awarded by National Science Foundation. The government has certain rights in the invention.

### FIELD OF THE DISCLOSURE

The present disclosure relates to data center power management, and specifically to characterizing the power consumption of a data center due to phase imbalance of one or more power distribution units (PDUs) therein.

### BACKGROUND

As the necessity for data centers continues to grow, the price of electricity has become a primary operating cost for many service providers. Accordingly, a recent influx of research has emerged focusing on strategies for maximizing the efficiency of data centers. Generally, strategies to make data centers more power and energy efficient are highly governed by electricity pricing models, in which the price of electricity is proportional to the power consumed, with extra penalties for power consumed within “peak” hours. Previous strategies have focused on designing data centers to reduce the peak power consumption thereof. For example, one power management strategy involves using an uninterrupted power supply (UPS) to store power during off-peak times for use during peak hours. As an additional example, the workload of various servers in a data center may be provisioned such that peak power consumption in different applications does not occur simultaneously. Yet another example includes using renewable energy to reduce peak power draw from the grid. While all of these solutions do reduce the peak power draw of a data center, they fail to account for inefficiencies in the data center due to phase imbalance of one or more power distribution units (PDUs) therein.

In the United States, PDUs are typically designed as three phase delta connected sources. In an ideal scenario, all three phases of the PDU should be balanced, meaning that the currents drawn from each one of the phases should be equal. If the currents are not balanced, the input power factor of the PDU deteriorates, resulting in an apparent power drawn from the power grid that is higher than the true or the useful power (i.e., active power) used by a load. Power factor is the ratio of active power to apparent power. Accordingly, when a PDU includes an imbalanced phase, the input current for each phase is higher than what it would be for the same load in a balanced configuration. The increased current is expended as reactive power, which does not deliver any useful power to the load, but contributes to higher currents, and higher I²R losses. Such an unbalanced configuration also requires a higher UPS capacity for the same true power of the load.

While recent research has attempted to characterize the power consumption of a data center attributable to phase imbalance in one or more PDUs, such approaches have failed to adequately do so. With adequate characterization of the power consumption of a data center attributable to phase imbalance in one or more PDUs, a designer can optimize the efficiency of the data center over a variety of phase imbalance conditions. Accordingly, there is a need for a method of characterizing the power consumption of a data center due to phase imbalance in one or more PDUs therein in order to correct the phase imbalance or otherwise operate the data center more efficiently.

### SUMMARY

The present disclosure relates to data center power management, and specifically to characterizing the power consumption of a data center due to phase imbalance of one or more power distribution units (PDUs) therein. In one embodiment, a method for characterizing the power consumption of a data center includes the steps of measuring one or more power consumption parameters associated with the data center when no workload is present, generating one or more workloads in the data center in which one or more three phase PDUs used to supply power to one or more servers in the data center include an imbalanced phase, measuring one or more power consumption parameters associated with the data center during the one or more generated workflows, and characterizing the power consumption of the data center due to phase imbalance of the one or more PDUs based on the measurements. By characterizing the power consumption of the data center due to phase imbalance based on empirical measurements, an accurate characterization of the power consumption attributable to phase imbalance can be achieved. With an accurate characterization of the power consumption attributable to phase imbalance in the data center, one or more operational parameters of the data center, for example, overprovisioning, server provisioning, etc. may be adjusted in order to improve the efficiency of the data center.

In one embodiment, a data center characterization system includes measuring circuitry, control circuitry, and processing circuitry. The measuring circuitry is configured to measure one or more power consumption parameters associated with the data center when no workload is present. Further, the measuring circuitry is configured to measure one or more power consumption parameters associated with the data center during various generated workloads in which one or more three phase PDUs used to supply power to one or more servers in the data center include an imbalanced phase. The control circuitry is configured to generate the one or more generated workloads. Finally, the processing circuitry is configured to characterize the power consumption of the data center due to phase imbalance of the one or more PDUs based on the measurements. By characterizing the power consumption of the data center due to phase imbalance based on empirical measurements, an accurate characterization of the power consumption attributable to phase imbalance can be achieved. With an accurate characterization of the power consumption attributable to phase imbalance in the data center, one or more operational parameters of the data center, for example, overprovisioning, server provisioning, etc. may be adjusted in order to improve the efficiency of the data center.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1 illustrates the connection of several servers in a data center to a three phase power distribution unit (PDU).

FIG. 2 illustrates a three phase delta PDU according to one embodiment of the present disclosure.

FIG. 3 illustrates a method for characterizing the power consumption in a data center due to phase imbalance of one or more PDUs therein.

FIG. 4 illustrates an apparatus for characterizing the power consumption of a data center due to phase imbalance of one or more PDUs therein.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

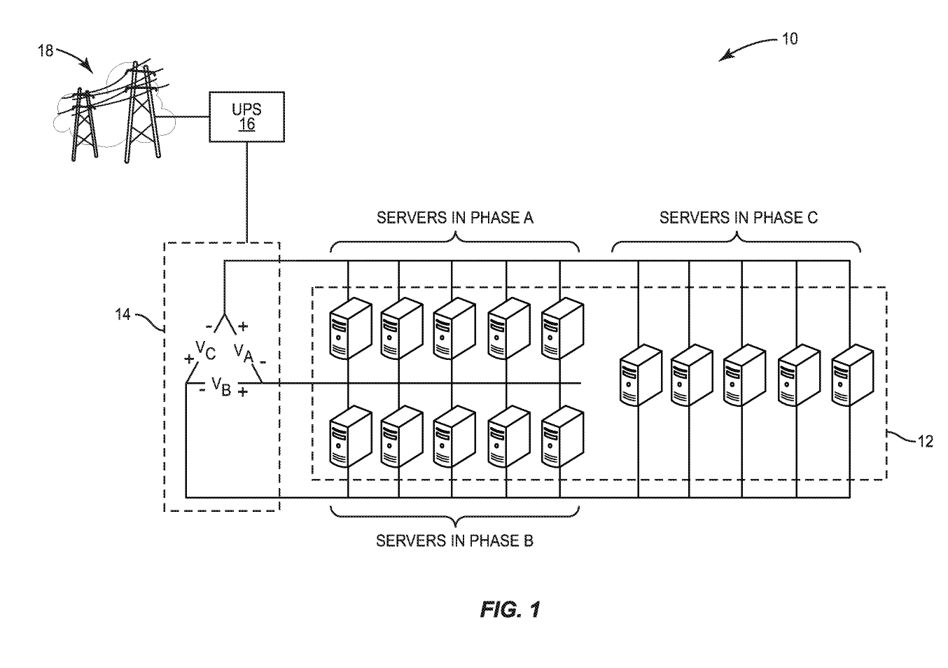

FIG. 1 shows a diagram illustrating an exemplary data center 10 according to one embodiment of the present disclosure. The data center 10 includes a number of servers 12, each connected between a particular phase of a power distribution unit (PDU) 14. The PDU 14 is in turn connected to an uninterrupted power supply (UPS) 16, which is connected to one or more power sources 18 such as a power grid and a renewable energy source. While only a single PDU 14 and a single UPS 16 are shown in FIG. 1, the data center 10 may include any number of UPSs and PDUs without departing from the principles described herein. In general, the number of UPSs and PDUs in the data center 10 will be selected based on the number of servers 12 therein. While the PDU 14 is shown as a three phase delta connected PDU, the principles of the present disclosure apply to any type of PDU, for example, star connected PDUs and the like. The UPS 16 may be any suitable type of UPS. For example, the UPS 16 may be a dual conversion UPS, a delta conversion UPS, or an alternating current (AC) to direct current (DC) UPS without departing from the principles described herein. Those of ordinary skill in the art will appreciate the particular connections to be made to and from the UPS 16 or UPSs 16 when utilizing the different types thereof.

In the embodiment in which the UPS 16 is a dual conversion UPS, the UPS 16 receives power from one or more power sources, such as a power grid or a renewable energy source in the form of an AC input power AC_IN. The UPS 16 converts the AC power into DC power, which is used to charge a battery in the UPS 16. The power from the battery is then supplied to the PDU 14 via an inverter as an AC output power AC_OUT. The PDU 14 distributes the power supplied by the UPS 16 to each one of the servers 12. In particular, the power from the UPS 16 is divided into three phases and delivered to one or more servers coupled to a particular phase of the PDU 14. The UPS 16 is associated with three ratings: a volt-amp rating (VAᵤₚₛ), which signifies how much apparent power the UPS 16 can deliver to a load, a wattage rating (Wᵤₚₛ), which signifies the amount of active power that the UPS 16 is capable of delivering, and a power factor rating (Pfᵤₚₛ), which signifies the ratio of active to apparent power that the UPS 16 is capable of delivering. The load to the UPS 16, in this case the PDU 14 also has a VA rating (VA_{load}) and a power factor rating (Pf_{load}). Several power supply regulations such as European Regulation No. EN61000-3-2 require a load to provide for power factor correction such that Pf_{load}≈1 and VA_{load}≈W_{load}. In general, the UPS 16 can supply power to a load if the VA rating of the load is less than that of the UPS 16 (i.e., VAᵤₚₛ>VA_{load}) and the wattage rating of the UPS 16 is more than that of the load (i.e., Wᵤₚₛ>W_{load}).

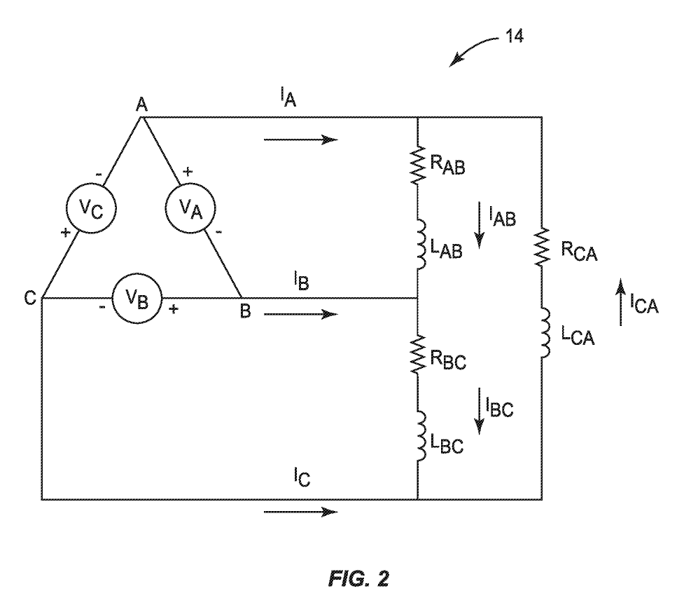

FIG. 2 shows an equivalent circuit of the PDU 14 and the servers 12 according to one embodiment of the present disclosure. As shown in FIG. 2, the PDU 14 includes a first phase (A), a second phase (B), and a third phase (C). A voltage between the first phase (A) and the second phase (B) is shown as a first phase voltage V_{A}. A voltage between the second phase (B) and the third phase (C) is shown as a second phase voltage V_{B}. A voltage between the third phase (C) and the first phase (A) is shown as a third phase voltage V_{C}. A current into the first phase (A) is illustrated as a first phase current I_{A}, a current into the second phase (B) is illustrated as a second phase current I_{B}, and a current into the third phase (C) is illustrated as a third phase current I_{C}. The servers 12 coupled between the first phase (A) and the second phase (B) are illustrated as a first phase equivalent resistance R_{AB} and a first phase equivalent inductance L_{AB}. The servers 12 coupled between the second phase (B) and the third phase (C) are illustrated as a second phase equivalent resistance R_{BC} and a second phase equivalent inductance L_{AB}. Finally, the servers 12 coupled between the third phase (C) and the first phase (A) are illustrated as a third phase equivalent resistance R_{CA} and a third phase equivalent inductance L_{CA}.

Ideally, the first phase voltage V_{A}, the second phase voltage V_{B}, and the third phase voltage V_{C} are equal in magnitude but shifted in phase by 120°. If the first phase voltage V_{A} is represented by V_{A}=Vₚ sin(ωt), the second phase voltage V_{B} is represented by V_{B}=Vₚ sin(ωt−120°), and the third phase voltage V_{C} is represented by V_{C}=Vₚ sin(ωt−240°), where Vₚ is the peak voltage (line-to-neutral) of each phase, ω is the angular velocity (i.e., 2π times the frequency of the supply), and t is time, then the line to line voltage for each phase can be expressed as shown in Equation (1).

V_{AB}=\sqrt{3}Vₚ sin(ωt+30°)

V_{BC}=\sqrt{3}Vₚ sin(ωt−90°)

V_{CA}=\sqrt{3}Vₚ sin(ωt−210°) (1)

The combination of the phase equivalent resistance and the phase equivalent inductance for each phase may be complex. Accordingly, the load currents I_{AB}, I_{BC}, and I_{CA} may have leading or lagging angles, as shown in Equation (2):

I_{AB}=\sqrt{2}I_{abrms} sin(ωt−ϕ_{A}+30°)=\sqrt{2}I_{abrms}(sin(ωt+30°)cos(ϕ_{A})−cos(ωt+30°)sin(ϕ_{A}))

I_{BC}=\sqrt{2}I_{bcrms} sin(ωt−ϕ_{B}−90°)=\sqrt{2}I_{bcrms}(sin(ωt−90°)cos(ϕ_{B})−cos(ωt−90°)sin(ϕ_{B}))

I_{CA}=\sqrt{2}I_{carms} sin(ωt−ϕ_{C}−210°)=\sqrt{2}I_{carms} sin(ωt−210°)cos(ϕ_{C})−cos(ωt−210°)sin(ϕ_{C}) (2)

where I_{AB} is the load current from phase (A) to phase (B), I_{BC} is the load current from phase (B) to phase (C), and I_{CA} is the load current from phase (C) to phase (A), I_{abrms} is the root mean square (RMS) current through the load between phase (A) and phase (B), I_{bcrms} is the RMS current through the load between phase (B) and phase (C), and I_{carms} is the RMS current through the load between phase (C) and phase (A). In phasor notation, I_{AB}=I_{abrms}[cos(ϕ_{A})−j sin(ϕ_{A})], I_{BC}=I_{bcrms}[cos(ϕ_{B})−j sin(ϕ_{B})], and I_{CA}=I_{carms}[cos(ϕ_{C})−j sin(ϕ_{C})]. The phase angles ϕ_{A}, ϕ_{B}, and ϕ_{C} depend on the characteristics of the load in each line. For a purely resistive load the phase angles are zero. If the load has an inductive component then the angles are positive. If the load has a capacitive component the phase angles are negative.

As discussed above, the real component of the various load currents delivers useful power and is referred to as active power. The imaginary component of the current is not useful and only results in loss of power due to the impedance of the power line of the particular phase. This imaginary component is referred to as reactive power. The apparent power delivered to a load is the vector sum of the active power and the reactive power. The ratio of the active power to the apparent power is called the power factor (Pf). The power factor can be quantified as shown in Equation (3).

Pf_{A}=cos(ϕ_{A})

Pf_{B}=cos(ϕ_{B})

Pf_{C}=cos(ϕ_{C}) (3)

Each line has an internal impedance equal to Zₗᵢₙₑ=Rₗᵢₙₑ+jωLₗᵢₙₑ or Rₗᵢₙₑ j/(ωCₗᵢₙₑ), which may be complex.

The line currents may be expressed in terms of the load currents using Kirchoff's laws, as shown in Equation (4).

I_{AB}=I_{AB}−I_{CA}

I_{B}=I_{BC}−I_{AB}

I_{C}=I_{CA}−I_{BC} (4)

Assuming ϕ_{A}=ϕ_{B}=ϕ_{C}=ϕ and plugging Equation (2) into Equation (4) shows the real and complex components of the line currents, as represented in Equation (5).

I_{A}=Iₗᵢₙₑ^{A} sin(ωt−ϕ−θ₁)

I_{B}=Iₗᵢₙₑ^{B} sin(ωt−ϕ−θ₂−120°)

I_{C}=Iₗᵢₙₑ^{C} sin(ωt−ϕ−θ₃−240°) (5)

where θ₁, θ₂, and θ₃ are phase offset angles indicating a deviation of the particular phase from a balanced scenario. The RMS line currents are then given by Equation (6).

$${I}_{line}^{A} = \sqrt{2} \sqrt{{I}_{abrms}^{2} + {I}_{carms}^{2} + {I}_{abrms} {I}_{carms}} \\ {I}_{line}^{B} = \sqrt{2} \sqrt{{I}_{abrms}^{2} + {I}_{bcrms}^{2} + {I}_{abrms} {I}_{bcrms}} \\ {I}_{line}^{C} = \sqrt{2} \sqrt{{I}_{bcrms}^{2} + {I}_{carms}^{2} + {I}_{bcrms} {I}_{carms}} \qquad ( 6 )$$

Equation (7) shows the phase offset angles in terms of the line currents in the PDU 14.

$$tan ( {θ}_{1} ) = \frac{1}{\sqrt{3}} \frac{{I}_{carms} - {I}_{abrms}}{{I}_{abrms} + {I}_{carms}} \\ tan ( {θ}_{2} ) = \frac{1}{\sqrt{3}} \frac{{I}_{abrms} - {I}_{bcrms}}{{I}_{abrms} + {I}_{bcrms}} \\ tan ( {θ}_{3} ) = - \frac{1}{\sqrt{3}} \frac{{I}_{bcrms} - {I}_{carms}}{{I}_{bcrms} + {I}_{carms}} \qquad ( 7 )$$

Accordingly, the total power loss due to line impedance is given by Equation (8).

Pₗₒₛₛ((Iₗᵢₙₑ^{A})²+(Iₗᵢₙₑ^{B})²+(Iₗᵢₙₑ^{C})²)Rₗᵢₙₑ (8)

Balancing a three phase delta connection means that the load in each phase is equal (i.e., I_{abrms}=I_{bcrms}=I_{carms}). An imbalanced three phase delta connection can lead to several implications. First, an imbalanced three phase delta connection leads to line loss due to line impedance. In a balanced three phase delta connection, the phase offset angles θ₁, θ₂, and θ₃ are equal to 0° and the total imaginary or reactive current delivered to a load is zero if the power factor of the load is unity. However, if there is a load imbalance then the phase offset angles θ₁, θ₂, and θ₃ deviate from zero and the total imaginary or reactive current drawn by the PDU 14 is non-zero. In other words, the reactive current introduces more line loss for an imbalanced load.

Second, phase imbalance leads to reactive power and thus the UPS 16 must supply more current to generate the same amount of power at the load. As the balance of the phases in the PDU 14 degrade, the power factor of the PDU 14 suffers. Accordingly, the active power of the PDU will reduce for the same amount of apparent power. To maintain the required amount of active power to the load, the UPS 16 has to supply more apparent power. As a result, a larger capacity UPS 16 is needed, thereby increasing the costs associated with the data center 10.

In general, the average active power delivered to the servers 12 through the PDU 14 does not change with phase imbalance. However, due to phase imbalance, the power factor deteriorates and hence there is reactive power. Thus, the apparent power from the source increases which results in increased heat losses through line impedance. The average active power delivered via the PDU 14 can be computed using Equation (9).

P_{active}^{avg}=VₚᵣₘₛIₗᵢₙₑ^{A} cos(θ₁+ϕ)+VₚᵣₘₛIₗᵢₙₑ^{B} cos(θ₂+ϕ)+VₚᵣₘₛIₗᵢₙₑ^{C} cos(θ₃+ϕ) (9)

where Vₚᵣₘₛ is RMS peak voltage and the phase offset angles θ₁, θ₂, and θ₃ and the line current values Iₗᵢₙₑ^{A}, Iₗᵢₙₑ^{B}, and Iₗᵢₙₑ^{C} are obtained from Equations (6) and (7). When there is no phase imbalance the line currents are equal and the angles are exactly 120° apart, resulting in a total active power of 3VₚᵣₘₛIₗᵢₙₑᵣₘₛ. However, as the phase becomes imbalanced, the power factor deviates from 1 in each line and the apparent power increases. The power factor due to phase imbalance is expressed in Equation (10).

$${Pf}_{imb} = \frac{{P}_{active}^{avg}}{{P}_{app}^{avg}} \qquad ( 10 )$$

Where P_{active}^{avg} denotes the average active power and Pₐₚₚ^{avg} denotes the average apparent power. Due to the decreased power factor caused by phase imbalance the apparent power increases, which causes an increase in the line loss Pₗₒₛₛ. However, given that the line loss is minimal, the percentage of line loss due to phase imbalance is often very small.

As a first example, consider that the line resistance for each phase of the PDU 14 is 0.0412 and the PDU 14 has a total load capacity of 6 kVA at 208 V (i.e., 2 kVA per phase). The active load on the PDU 14 is only 2 kVA/2 kW, consisting of three servers with a unity power factor and each consuming 666.6 W. If the three servers are distributed to three different branches, one between phase (A) and phase (B), one between phase (B) and phase (C), and one between phase (C) and phase (A), each server draws 666.6 W/208 V=3.2408 A. Accordingly, each phase has a current equal to \sqrt{3}*3.2048 A=5.5509 A. The I²R loss on each phase is thus (5.5509 A)²*0.04 Ω=1.2325 W. Thus the overall power loss for all three phases is 3.69749 W or 0.18% of the load.

As a second example, the PDU 14 discussed above includes the three servers all connected on the same branch, between phase (A) and phase (B). The current on each of phase (A) and phase (B) is equal to 2000 W/208 V=9.6154 A. The current on phase (C) is zero. The total I²R loss on each of phase (A) and phase (B) is equal to (9.6154 A)²*0.04 Ω=3.6982 W. Loss on both of the phases is thus equal to 7.3964 W or 0.37% of the load.

As the examples above show, loss increases for an unbalanced load, from 0.18% to 0.37%. Theoretically, the loss is about double in the second example when compared to the first example. The increase in the loss is attributable to a degradation in the power factor in the second example wherein the PDU 14 includes an unbalanced phase. The poor power factor results in a larger current in the PDU 14 (the sum of all currents in the PDU 14 is 19.2308 A in the second example as opposed to 16.6527 A in the first example), leading to larger line losses. Further, the current in the second example is spread over two wires rather than three, thus increasing the losses in the lines from heat.

The foregoing principles similarly apply to different types of PDUs. For example, the foregoing principles may apply to a star connected PDU, as discussed below. An exemplary star connected PDU may be coupled to a 230 V line to neutral supply with a total capacity of 6 kVA (i.e., 2 kVA per phase), have a line resistance of 0.0412, and include three servers having a load of 666.6 W at unity power factor in each phase. If one of the servers in each phase of the PDU is powered ON while the rest remain OFF, the current in each phase I_{A}=I_{B}=I_{C}=666.6 W/230 V=2.8983 A. The I²R loss in each phase is then (2.8983 A)²*0.04Ω=0.3360 W, and the total I²R loss for the PDU is 1.0080 W or 0.05% of the load power. If three of the servers in a first phase of the PDU are ON while the rest of the servers are OFF, the current in the first phase is given by I_{A}=2000 W/230 V=8.6957 A. The I²R loss in the first phase is then given by (8.6957 A)²*0.04 Ω=3.0246 W. The total loss is then equal to 6.0491 W or 0.302% of the load power. Accordingly, phase imbalance in the star connected PDU results in a six fold increase in line loss.

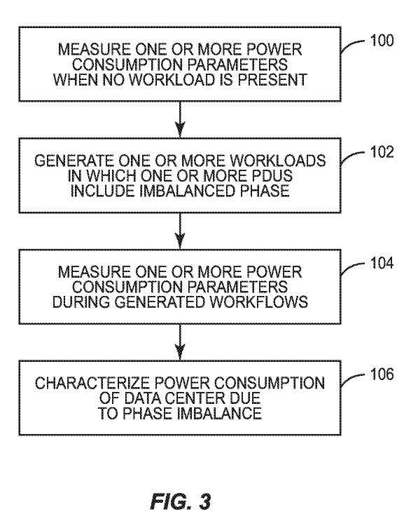

As shown above, phase imbalance can have a significant impact on the efficiency of a PDU 14 and thus the power consumption of a data center 10. In order to compensate for these inefficiencies, an accurate characterization of the power consumption attributable to phase imbalance in the data center 10 must first be achieved. Absent an accurate characterization of the power consumption attributable to phase imbalance, one may be forced to significantly overprovision the power system of a data center in order to be assured that enough power will be available for the servers therein, resulting in unnecessary power consumption and expense. Accordingly, FIG. 3 illustrates a method for accurately characterizing the phase imbalance of the data center 10 according to one embodiment of the present disclosure.

First, one or more power consumption parameters of the data center 10 are measured when there is no workload present in the data center 10 (step 100). A no workload condition occurs when none of the servers 12 are provisioned for a particular task and thus are inactive. Accordingly, during a no workload condition, the phases of the PDU 14 will be balanced. The one or more power consumption parameters of the data center 10 may be measured by measuring circuitry located in the PDU 14 itself or in another component of the data center 10, such as the UPS 16. The one or more power consumption parameters may include, for example, an active power of the PDU 14, an apparent power of the PDU 14, a power factor of the PDU 14, or a current through one or more phases of the PDU 14. Next, one or more workloads are generated in the data center 10 in which the phases of the PDU 14 are imbalanced (step 102). As discussed above, a phase imbalance condition occurs when the current drawn by one of the phases of the PDU 14 is different from the others. Accordingly, generating one or more workloads in which a phase imbalance condition is present may involve provisioning an unequal number of servers 12 in at least one of the phases of the PDU 14, such that the current through each of the phases of the PDU 14 are not equal. In one embodiment, generating one or more workloads in which a phase imbalance condition is present includes provisioning a number of servers 12 in the data center 10 such that the current distribution in the PDU 14 varies between the phases. A first workload may be generated in which a number of servers 12 are provisioned in order to produce a worst case phase imbalance scenario in which all of the provisioned servers 12 are located on a single phase. Additional workloads may then be generated such that various phase imbalance conditions occur that are between a balance phase condition and the worst case scenario for phase imbalance.

One or more power consumption parameters of the data center 10 are then measured during the generated workflows (step 104). As discussed above, the one or more power consumption parameters may include, for example, an active power of the PDU 14, an apparent power of the PDU 14, a power factor of the PDU 14, or a current through one or more phases of the PDU 14. The one or more power consumption parameters of the data center 10 may be measured by measuring circuitry located in the PDU 14 itself or in another component of the data center 10, such as the UPS 16. Finally, the power consumption of the data center 10 attributable to phase imbalance of the PDU 14 is characterized (step 106). Characterizing the power consumption of the data center 10 due to the phase imbalance of the PDU 14 may involve comparing the power consumption measurements made when no workflow is present to those made during the one or more generated workflows in which a phase imbalance condition is present and/or solving any number of the equations described above using the power consumption measurements. Characterizing the power consumption of the data center 10 in this manner allows for a quantitative analysis of the power consumption due to phase imbalance, leading to exceedingly accurate results. These results may then be relied upon to determine a necessary amount of overprovisioning for the data center 10, to provision one or more servers 12 in the data center 10, or otherwise improve the efficiency of the data center 10.

In one embodiment, the characterization of the power consumption of the data center 10 due to phase imbalance of the PDU 14 is used to provision the workload of one or more servers 12 in order to retain a balanced phase. In some situations, characterizing the power consumption of the data center 10 may show that for relatively small loads (e.g., when the utilization of servers 12 is less than about 25%), that balancing the phase of the PDU 14 is detrimental and results in additional losses when compared to different power management schemes such as thermal aware server provisioning (TASP), while for larger phase (e.g., when the utilization of servers 12 is greater than about 25%) balancing the loads of the PDU 14 results in increases in the efficiency of the data center 10. This may be due to the non-linear nature of the line loss with respect to phase imbalance and current magnitude.

In one example wherein the data center 10 is utilized at 10% and there are three chassis operating at 14.85 A each for a total load of 43.74 A distributed across four PDUs 14, the balance is obtained by distributing the load equally to all three phases of one of the PDUs 14. This results in a configuration where one PDU 14 has a 14.85 A load current in each phase and the other PDUs 14 have no load. The total line current on each line of the active PDU 14 is thus 25.72 A as obtained from Equation (4) above. This is a higher current magnitude than the case where we have an imbalanced load, as discussed below. The total line loss for the balanced case is 3*661.6*Rₗᵢₙₑ=1984.8Rₗᵢₙₑ. For an unbalanced case in which each of three PDUs 14 have 14.85 A on one phase and zero on the other two phases and the last PDU 14 goes without a load, the total line current for the active PDUs 14 is 14.85 A for the utilized lines with zero current for the third line. This current is lower in magnitude than in the balanced case. Accordingly, the line loss on each of the first three PDUs 14 is 2*220.5225*Rₗᵢₙₑ=1323.135Rₗᵢₙₑ. This occurs due to load consolidation on a lesser number of PDUs, which increases the current on each line. However, as the utilization of the data center 10 increases the opportunities for load consolidation are reduced and the benefits of phase balancing become more conspicuous. These trade-offs are subject to the significance of the loss.

In one embodiment, the load current of the PDU 14 is varied from 60 A to 100 A in increments of 20 A. The phase imbalance is then characterized using an imbalance factor, which is defined as the deviation from average current and the current due to phase imbalance to the average current, as the salient measurement. The phase imbalance factor may be varied from 0 (balanced) to 2 (maximum imbalance), and the line loss and power factor characterized for each of these cases. The results may be used to determine a necessary overprovisioning for the data center 10 and/or provision one or more servers 12.

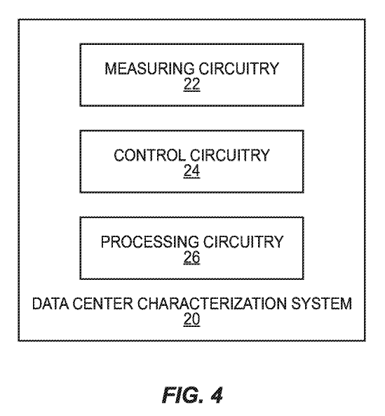

FIG. 4 shows a data center characterization system 20 that may be used in conjunction with the data center 10 according to one embodiment of the present disclosure. The data center characterization system 20 includes measuring circuitry 22 configured to measure one or more power consumption parameters of the data center 10 both during a no workload condition and during a phase imbalance condition. The data center characterization system 20 further includes control circuitry 24 configured to generate one or more workloads in the data center 10 in which the phase of one or more PDUs 14 are imbalanced. Finally, the data center characterization system 20 includes processing circuitry 26 configured to characterize the power consumption of the data center 10 attributable to phase imbalance, which may be accomplished via any of the methods discussed above. The resulting power consumption data may be used to control one or more operational parameters of the data center 10 including overprovisioning, server provisioning, and the like, in order to increase the efficiency of the data center 10.

Those skilled in the art will recognize improvements and modifications to the preferred embodiments of the present disclosure. All such improvements and modifications are considered within the scope of the concepts disclosed herein and the claims that follow.

What is claimed is:

1. A data center, comprising:
a power distribution unit (PDU) configured to:
output a first phase, a second phase, and a third phase of AC power;
measure one or more power consumption parameters for each of the first phase, the second phase, and the third phase during a no workload condition of the data center; and
measure the one or more power consumption parameters for each of the first phase, the second phase, and the third phase during a phase imbalance condition in the data center;
a first set of servers coupled to the first phase of AC power output by the PDU;
a second set of servers coupled to the second phase of AC power output by the PDU; and
a third set of servers coupled to the third phase of AC power output by the PDU;
wherein:
the first set of servers comprises more servers than the second set of servers; and
the one or more power consumption parameters comprise one or more of an active power, an apparent power, a power factor, or a current.

2. The data center of claim 1, wherein the PDU is further configured to characterize power consumption attributable to phase imbalance based on the one or more power consumption parameters during the no workload condition and during the phase imbalance condition.

3. The data center of claim 2, wherein, based on the power consumption characterization, the data center causes workloads to shift from the first set of servers to the second set of servers when the phase imbalance condition occurs in order to balance the first phase, the second phase, and the third phase.

4. The data center of claim 3, wherein the data center causes workloads to shift from the first set of servers to the second set of servers when the phase imbalance condition occurs and utilization of the first set of servers exceeds a threshold.

5. The data center of claim 4, wherein the data center operates under a thermal aware server provisioning (TASP) scheme when utilization of the first set of servers is below the threshold.

6. The data center of claim 4, wherein the data center causes the workloads to shift from the first set of servers to the second set of servers based on the physical proximity of the first set of servers to one another when utilization of the first set of servers is below the threshold.

7. The data center of claim 2, wherein the PDU is further configured to determine a necessary amount of overprovisioning based on the power consumption characterization.

8. The data center of claim 1, further comprising an uninterruptible power supply (UPS) coupled to an input of the PDU.

9. The data center of claim 8, wherein the PDU is further configured to determine a capacity of the UPS for supplying power to the PDU based on the one or more power consumption parameters during the no workload condition and during the phase imbalance condition.

10. The data center of claim 1, wherein the PDU is a delta connected PDU.

11. The data center of claim 1, wherein the phase imbalance condition comprises a maximum imbalance in the phases of the PDU.

12. The data center of claim 1, wherein the phase imbalance condition comprises a first phase imbalance at a first load current of the PDU and a second phase imbalance at a second load current of the PDU higher than the first load current.

13. The data center of claim 12, wherein the PDU is further configured to characterize power consumption attributable to phase imbalance based on the one or more power consumption parameters during the no workload condition, during the first phase imbalance, and during the second phase imbalance.

14. The data center of claim 13, wherein, based on the power consumption characterization, the data center causes workloads to shift from the first set of servers to the second set of servers when another phase imbalance condition occurs in order to balance the first phase, the second phase, and the third phase.

15. The data center of claim 13, wherein the PDU is further configured to characterize the power consumption attributable to phase imbalance based on a line loss for each of the first phase, the second phase, and the third phase during the no workload condition, during the first phase imbalance, and during the second phase imbalance.

16. The data center of claim 15, wherein the data center causes workloads to shift from the first set of servers to the second set of servers when another phase imbalance condition occurs in order to minimize a total line loss based on the power consumption characterization.
